(19) United States
(12) Patent Application Publication
(10) Pub. No.: US 2016/0024688 A1
(43) Pub. Date: Jan. 28, 2016

(54) FABRICATION AND/OR APPLICATION OF ZINC OXIDE CRYSTALS WITH INTERNAL (INTRA-CRYSTALLINE) POROSITY

(71) Applicants: Jacob Richardson, Santa Barbara, CA (US); Evan O'Hara, Santa Barbara, CA (US)

(72) Inventors: Jacob Richardson, Santa Barbara, CA (US); Evan O'Hara, Santa Barbara, CA (US)

(73) Assignees: Seoul Semiconductor Co., Ltd., Gyeonggi-do (KR); Solution Deposition Systems, Inc., Goleta, CA (US)

(21) Appl. No.: 14/341,700

(22) Filed: Jul. 25, 2014

(51) Int. Cl. C30B 29/16; C30B 19/10; C30B 19/00; C30B 7/14; C30B 7/04; H01L 35/22; C30B 30/02; C01G 9/02; B01J 23/06; H01L 51/52; H01L 33/58; C30B 7/10; C30B 29/66

(52) U.S. Cl. CPC C30B 29/16; C30B 7/10; C30B 19/103; C30B 19/00; C30B 7/14; C30B 7/04; C30B 29/66; C30B 30/02; C01G 9/02; B01J 23/06; H01L 51/5275; H01L 33/58; H01L 35/22; C01P 2006/40; H01L 2251/305

(57) ABSTRACT

Briefly, an embodiment comprises fabricating and/or uses of one or more zinc oxide crystals in which one or more zinc oxide crystals have intra-crystalline porosity other than incidental intra-crystalline porosity.

### FIELD

Subject matter disclosed herein relates to crystalline zinc oxide, such as processes for preparation thereof and/or uses thereof, for example.

Information:

In a variety of different contexts, too numerous to conveniently describe here, it may be desirable for a material to have certain properties along with being electrical conductive, such as optical and/or thermal type properties, as examples. As an illustration, a transparent and electrically conductive substance may be used to manufacture films, layers and/or coatings (hereinafter, “layer” used without “film and/or coating” is nonetheless understood in context to mean “film, layer and/or coating”) for a variety of optoelectronic devices, such as, to provide some non-limiting examples, a light emitting diode (LED); a laser diode; an organic light emitting diode (OLED); a photovoltaic cell; a liquid crystal display; and/or a touch sensor display.

One substance that is employed, for example, is zinc oxide. Processes to produce zinc oxide in a less complex and/or less costly manner so as to make it suitable for use in these and/or other applications continue to be sought.

### BRIEF DESCRIPTION OF THE DRAWINGS

Claimed subject matter is particularly pointed out and distinctly claimed in the concluding portion of this specification. However, both as to organization and/or method of operation, together with objects, features, and/or advantages thereof, it may best be understood by reference to the following detailed description if read with the accompanying drawings in which:

FIG. 1 is a sample flowchart showing an embodiment of a sample process;

FIGS. 2A, 2B and 2C respectively are a variety of corresponding pairs of images showing variations in intra-crystalline porosity resulting from employing variations in process conditions for several sample process embodiments;

FIGS. 3A and 3B are schematic illustrations of respective embodiments of light emitting diode (LED) devices;

FIGS. 4A, 4B and 4C are schematic illustrations of respective embodiments of organic light emitting diode (OLED) devices; and

FIG. 5 are schematic illustrations of several embodiments of thermoelectric devices.

Reference is made in the following detailed description to accompanying drawings, which form a part hereof, wherein like numerals may designate like parts throughout to indicate corresponding and/or analogous components and/or aspects. It will be appreciated that components and/or aspects illustrated in the figures have not necessarily been drawn to scale, such as for simplicity and/or clarity of illustration. For example, dimensions may be exaggerated relatively speaking. Further, it is to be understood that other embodiments may be utilized. For example, structural and/or other changes may be made without departing from claimed subject matter. It should also be noted that directions and/or references, for example, up, down, top, bottom, and so on, may be used to facilitate discussion of drawings and/or are not intended to restrict application of claimed subject matter. Therefore, the following detailed description is not to be taken to limit claimed subject matter and/or equivalents.

### DETAILED DESCRIPTION

References throughout this specification to one implementation, an implementation, one embodiment, an embodiment and/or the like means that a particular feature, structure, and/or characteristic described in connection with a particular implementation and/or embodiment is included in at least one implementation and/or embodiment of claimed subject matter. Thus, appearances of such phrases, for example, in various places throughout this specification are not necessarily intended to refer to the same implementation or to any one particular implementation described. Furthermore, it is to be understood that particular features, structures, and/or characteristics described are capable of being combined in various ways in one or more implementations and, therefore, are within intended claim scope, for example. In general, of course, these and other issues vary with context. Therefore, particular context of description and/or usage provides helpful guidance regarding inferences to be drawn.

Likewise, in this context, the terms “coupled”, “connected,” and/or similar terms are used generically. It should be understood that these terms are not intended as synonyms. Rather, “connected” is used generically to indicate that two or more components, for example, are in direct physical, including electrical, contact; while, “coupled” is used generically to mean that two or more components are potentially in direct physical, including electrical, contact; however, “coupled” is also used generically to also mean that two or more components are not necessarily in direct contact, but nonetheless are able to co-operate and/or interact. The term coupled is also understood generically to mean indirectly connected, for example, in an appropriate context.

The terms, “and”, “or”, “and/or” and/or similar terms, as used herein, include a variety of meanings that also are expected to depend at least in part upon the particular context in which such terms are used. Typically, “or” if used to associate a list, such as A, B or C, is intended to mean A, B, and C, here used in the inclusive sense, as well as A, B or C, here used in the exclusive sense. In addition, the term “one or more” and/or similar terms is used to describe any feature, structure, and/or characteristic in the singular and/or is also used to describe a plurality and/or some other combination of features, structures and/or characteristics. Likewise, the term “based on” and/or similar terms are understood as not necessarily intending to convey an exclusive set of factors, but to allow for existence of additional factors not necessarily expressly described. Of course, for all of the foregoing, particular context of description and/or usage provides helpful guidance regarding inferences to be drawn. It should be noted that the following description merely provides one or more illustrative examples and claimed subject matter is not limited to these one or more examples; however, again, particular context of description and/or usage provides helpful guidance regarding inferences to be drawn.

In this context, a zinc oxide crystal comprises a material primarily of zinc and oxygen atoms arranged at least partially in a crystalline phase (e.g., a crystal structure) for zinc oxide, such as, for example, the Wurtzite crystal structure. A zinc oxide crystal may contain atoms other than zinc and oxygen in a manner in which those atoms substitute for a zinc or oxygen atom in the crystal structure and/or reside in interstitial regions of the crystal structure. A zinc oxide crystal may likewise contain atomic vacancies, dislocations, and/or other crystal defects, as well as inclusions of second phases.

In general, if fabricating ZnO crystals, dense crystals are typically desired and produced. In this context, a dense crystal refers to a crystal structure having no measurable intra-crystalline porosity or having only a negligible amount thereof. Typically, having more than a negligible amount of intra-crystalline pores, for example, may potentially interfere with typically desired properties and, therefore, has generally been viewed as undesirable. However, with that said, there are examples of porous materials in which presence of pores has been shown to be beneficial or has at least been shown to have a potential for beneficially affecting material properties. One difference, however, from prior approaches has to do with intra-crystalline porosity. In prior approaches in which a process was specifically formulated to result in porosity for a substance, the porosity was generally of an inter-crystalline nature rather than intra-crystalline. This latter statement is particularly true for zinc oxide.

A presence of pores contained within an individual zinc oxide crystal is referred to in this context as intra-crystalline porosity. Likewise, porosity between individual grains of a polycrystalline material, here zinc oxide, comprising a plurality of connected crystalline grains, is referred to in this context as inter-crystalline porosity. Pores contained within one or more zinc oxide crystal or crystals may be distributed at least approximately uniformly or at least approximately non-uniformly about a volume of a crystal or crystals in a random or in a systematic manner. Pores may be of uniform size and shape or pores may be of non-uniform size and shape, again, varying in a random or in a systematic manner.

Potential influence of presence of intra-crystalline porosity on material properties, particularly ZnO, is discussed in some detail below. However, in general, a process in which porosity might be generated in a manner capable of at least partially affecting features of the generated intra-crystalline porosity might have potential uses in connection with one or more materials, here ZnO, for at least some applications. Porous materials are valuable for a variety of purposes at least in part due to high surface area and/or composite properties that may potentially result from a volumetric combination of a primary solid material (e.g., a matrix material) that surrounds the pores and a secondary material that fills the pores, which may comprise a gas or vacuum in some cases. Intra-crystalline porosity may, in particular, allow grain size and its associated geometry to largely be ‘decoupled’ from pore size and its associated geometry. In contrast, for inter-crystalline porosity, grain size and pore size may be at least partially related as a result of the pores being formed between the grains.

Zinc oxide comprises a wide band-gap semiconductor material. In various forms, it may have desirable electrical, optical, electro-mechanical, and/or biomedical properties, as shall be described in more detail. As a consequence, an ability to create one or more ZnO crystals with intra-crystalline porosity in which porosity varies could be of use in many current and/or future applications potentially.

As a non-limiting example, an application where ZnO materials are of growing importance is as an alternative to indium tin oxide (ITO), such as in transparent conductive layer applications, for example. Energy generation technologies (e.g., photovoltaic solar cells) and/or energy conservation technologies (e.g., light emitting diode (LED) devices and/or organic light emitting diodes (OLED) devices), as merely examples, may utilize transparent conductive layers (e.g., as electrodes).

Optoelectronic device applications that use transparent conductive layers, such as those just mentioned, however, may also benefit from use of layers that may be employed to, in effect, manage aspects and/or features of light passing into and/or out of a device. For example, one or more light management layers, may, as examples, potentially affect one or more of the following: light reflection, light extraction, light trapping, light guiding, light out-coupling, light in-coupling, light scattering and/or light diffusing. In this context, anti-reflection and/or similar terms are intended to mean a reduction in light reflection, such as by a surface of a layer, for example. In this context, light trapping and/or similar terms are intended to mean an increase in the fraction of light captured, such as by passing through a surface of a layer and/or entering though a surface of a layer and being absorbed in a device such that features and/or aspects thereof may be modified so as to potentially and/or ultimately affect properties of the light. Thus, in addition to affecting an amount of light captured, distribution of spectral and/or directional aspects of light that is captured, as examples, may be affected. Furthermore, in this context, light extraction and/or similar terms are intended to mean an increase in the fraction of light extracted, such as being extracted by passing through a surface of a layer and/or being extracted from a device though a surface of a layer such that features and/or aspects thereof may be modified so as to potentially and/or ultimately affect properties of the light. Thus, in addition to affecting an amount of light extracted, distribution of spectral and/or directional aspects of the light that is extracted, as examples, may be affected.

Thus, one or more light management layers may reduce light reflection, which shall be described more detail, and/or otherwise modify aspects and/or features associated with passage of light into or out of a device, e.g., such as one or more ‘light extraction’ layers and/or one or more ‘light trapping’ layers. An ability to incorporate transparent conductive properties and other optical properties, such as anti-reflective, light extraction, and/or light trapping properties, into a single film, layer and/or coating, and/or a single set of related films, layers and/or coatings, has potential to reduce manufacturing complexity, manufacturing cost, and/or potential to improve operating performance.

An embodiment of a method of synthesizing one or more ZnO crystals having internal porosity, e.g., intra-crystalline porosity, may employ an aqueous solution type crystallization process, as described below. In general, baseline processes for synthesizing one or more ZnO crystals, such as examples discussed below, are currently known. In this context, a baseline process and/or similar terms are intended to refer to a process to synthesize one or more ZnO crystals in which the process is not specifically formulated to affect intra-crystalline porosity of the one or more resulting ZnO crystals, in whole or in part. Thus, as examples, several baseline low temperature processes for synthesizing one or more zinc oxide crystals via an aqueous solution are discussed below to provide illustrations that may be contrasted with a later discussion of illustrative processes for synthesizing one or more zinc oxide crystals in which those processes are specifically formulated to affect intra-crystalline porosity at least partially.

Thermodynamic calculations disclosed in “Controlling Low Temperature Aqueous Synthesis of ZnO: Part 1, Thermodynamic Analysis,” by Jacob J. Richardson and Frederick F. Lange, Cryst. Growth Des. 2009, 9(6), pp. 2570-2575, (hereinafter “Part 1”) predict that aqueous solutions containing ammonia and in a certain pH range may have higher solubility for ZnO at room temperature (e.g., 25 degrees C.) than at near boiling temperatures (e.g., 90 degrees C.). Likewise, figures included in Part 1 show results of ZnO solubility calculations made as a function of pH, ammonia concentration, and temperature. For example, these figures indicate that ZnO solubility is expected to be lower at 90 degrees C. than at room temperature.

Likewise, experimental results disclosed in “Controlling Low Temperature Aqueous Synthesis of ZnO: Part II, A Novel Continuous Circulation Reactor,” by Jacob J. Richardson and Frederick F. Lange, Cryst. Growth Des. 2009, 9(6), pp. 2576-2581 (hereinafter “Part 2”), demonstrate that the predictions in Part 1 appear reasonably accurate for ZnO synthesized from solutions containing between 0.25 and 1.0 mol/L ammonia and having pH between 10 and 12, for example. Of course, example conditions, such as these, are understood to be merely illustrative of a host of possible other pH and/or ammonia concentration solution conditions capable of synthesizing ZnO.

In an illustrative example, an aqueous growth solution may contain dissolved zinc, ammonia and/or another source of similarly acting complexing ligands, and an acid or base to achieve a desired pH. It may at times be desirable to simplify fabrication processes for formation of ZnO; thus, acids and bases which do not form complexes with zinc under particular pH and/or temperature conditions may be used.

Zinc may be supplied to a growth solution in a variety of way, including by dissolving a zinc containing compound, in this context referred to as a zinc nutrient. A zinc nutrient may comprise a soluble zinc salt, such as, for example, zinc nitrate. With higher solubility of ZnO at room temperature than at higher temperatures, ZnO may itself be employed as a zinc nutrient for ammonia containing solutions of appropriate pH, as disclosed in Part 1 and Part 2.

Besides ammonia, other sources of ammine ligands, as well as other ligands which may result in a similar ZnO solubility, for example, may be employed as well. In this context, ammine refers to a ligand in a metal complex containing at least one ammine (—NH₃) ligand. Aqueous solutions of ammonia dissolved in water are also commonly referred to as an ammonium hydroxide solution, ammonia water, aqua ammonia, household ammonia, and/or simply ammonia. Ammine ligands may also be supplied to an aqueous solution by dissolving ammonium salts. Examples include, but are not limited to, simple inorganic and/or organic salts, such as ammonium chloride, ammonium nitrate, ammonium acetate, ammonium carbonate, triammonium citrate, etc. Ammine ligands may also be supplied as part of a soluble coordination compound or double salt. Additionally, ammine ligands may be supplied by in situ decomposition of another compound, such as urea and/or hexamine, for example. Other ligands which may form aqueous complexes of Zn (II) may result in a temperature range of decreasing solubility of ZnO with increasing temperature and may, therefore, also be used. Other ligands with potential to behave in this manner include, but are not limited to, water soluble primary amines, secondary amines, tertiary amines, and/or polyamines. Non-nitrogen containing ligands which form complexes and result in desired solubility behavior for ZnO may potentially also be used.

In addition to the foregoing, it is, of course, also possible to use more complex growth solutions containing additives to modify ZnO growth and/or composition. As discussed later, if a process is formulated to at least partially affect intra-crystalline porosity, process parameters, such as these, may potentially be modified, as discussed in some detail below; however, here, these parameters are mentioned in connection with an example baseline process and independent of considerations regarding intra-crystalline porosity. Additives, such as citrate ions, are known to affect morphology with respect to ZnO synthesized in an aqueous solution. For example, citrate ions may be utilized in a growth solution through addition of soluble metal citrate salts and/or citric acid. Examples of other additives that may show similar behavior include other poly-anionic molecules, surfactants, water soluble polymers, and/or biomolecules, for example.

Additives may also be employed in a growth solution to potentially affect a synthesized composition of ZnO. Again, here, these parameters are mentioned independent of considerations regarding intra-crystalline porosity. As a few non-limiting examples, additions, for example, may include sources of group III elements, such as Al, Ga, or In, which are known to provide N-type doping to ZnO. Others include group I elements, such as Li, which are known to reduce conductivity of ZnO, and/or isovalent elements, like Mg and/or Cd, which are known to have a potential to modify bandgaps with respect to ZnO if used as dopants.

Addition of dopant additives, such as those mentioned above, could be achieved by dissolving a soluble dopant containing chemical. For example, Al may be supplied by dissolution into a solution of Al nitrate. Similar to the way that ZnO may be utilized as a zinc nutrient, addition of dopant additives may also be achieved by dissolving generally low solubility dopant containing chemicals under appropriate dissolution conditions. In this context, dissolution condition refers to a situation in which the free energy for the dissolution reaction is negative so that dissolution takes place. For example, an aluminum oxide powder could be mixed with a ZnO powder in an applicable dissolution condition. A third method could be to dope a Zn nutrient before using it, e.g., using an Al doped ZnO powder as a nutrient. The second and third methods have an advantage of maintaining a concentration of dopant in solution throughout growth. However, if a small amount of dopant is being incorporated into ZnO relative to solution concentration, solution concentration may not change significantly, and the first method may also work satisfactorily.

Synthesis of one phase of material from another, such as zinc oxide crystallization using an aqueous growth solution, may involve nucleation of a new phase. According to nucleation theory, a free energy change, delta G (AG) can be expressed as a sum of a volumetric energy term, which goes as the radius, r, of the nucleus cubed, and a surface energy term, which goes as the radius squared, substantially in accordance with the following relation:

$$Δ G = \frac{4}{3} π {r}^{3} {G}_{v} + 4 π {r}^{2} γ$$

The volume term is proportional to a volumetric chemical free energy, Gᵥ. If a chemical reaction leading to a new phase is energetically favorable, that term is negative; if a reverse reaction is favorable, the term is positive. If further from equilibrium, the greater the magnitude of the term. If the reaction is in chemical equilibrium, the term is zero.

A nucleation process implies that a new surface is created, so a surface energy term is positive and proportional to surface energy, gamma, as shown above. A square of the nucleus radius compared to the cube suggests a surface term will dominate for small radii and a volume term will dominate at large radii.

Although these relations are specific to homogeneous nucleation, behavior for other forms of nucleation can be expressed similarly. For crystallization from a solution phase, non-homogeneous nucleation typically results in a lower value for delta G and, thus, a higher nucleation rate. From typically least to most thermodynamically favorable, types of nucleation include: homogeneous, heterogeneous, heteroepitaxial, and homoepitaxial (growth).

As discussed in Part 1, heating a growth solution lowers solubility of ZnO in solution, in this context. Furthermore, unless ZnO is precipitated or deposited from solution, a supersaturation condition may be created. In thermodynamic terms, supersaturation means that equilibrium has shifted towards synthesis of ZnO so that Gᵥ is negative. Greater supersaturation means a more negative Gᵥ; a more negative Gᵥ means a lower energy barrier to nucleation, and thus, a greater nucleation rate.

However, if a growth solution is heated relatively slowly; magnitude of Gᵥ may be limited. If Gᵥ reaches an appropriate value, nucleation of ZnO may start to occur at an appreciable rate. If a ZnO seed is present, homoepitaxial nucleation, or growth, may occur at relatively low supersaturation. Given an appropriate substrate, heteroepitaxial nucleation may occur for a higher superstation. If a substrate present has no epitaxial relationship with ZnO, heterogeneous nucleation may occur at an even higher supersaturation. If no heterogeneous nucleation sites are available, homogeneous nucleation may occur but with even higher supersaturation. If nucleation begins, growth of nuclei allows movement back towards equilibrium, thereby reducing supersaturation and Gᵥ. If a maximum kinetically allowed growth rate of ZnO is faster than a rate of change of supersaturation, overall a solution may remain near equilibrium. A rate of change in supersaturation may be quantified in a supersaturation rate equation, for example.

Although a potential relationship between rate of crystal growth and generation of intra-crystalline porosity is discussed later, it is noted here that a similar relationship may exist in connection with nucleation for similar reasons. Thus, in general, slower nucleation may reduce internal porosity whereas faster nucleation may increase porosity. However, this later observation is made here solely for convenience of the reader and is not intended to relate to a baseline process as defined in this context.

Different types of nucleation may be employed in a baseline process for synthesizing one or more crystals of ZnO. For example, in one illustrative embodiment, a baseline process may be employed in which an epitaxial ZnO film is grown from a low temperature aqueous solution. For example, a zinc oxide film may be grown from an aqueous solution using a two-part process, such as has been described in: Andeen, D.; Kim, J. H.; Lange, F. F.; Goh, G. K. L.; Tripathy, S., Lateral Epitaxial Overgrowth of ZnO in Water at 90° C. Advanced Functional Materials 2006, 16, (6), 799-804; and in Thompson, D. B.; Richardson, J. J.; Denbaars, S. P.; Lange, F. F., Light Emitting Diodes with ZnO Current Spreading Layers Deposited from a Low Temperature Aqueous Solution. Applied Physics Express 2009, 2, 042101-042101.

In a first part, a seed layer may be nucleated and, in a second part, a thicker ZnO film may be grown. For seed layer deposition, a substrate, such as a single MgAl₂O₄ wafer or an epitaxial GaN layer on a single crystal sapphire wafer, for example, may be inserted into an aqueous solution of zinc nitrate and ammonium nitrate at 90° C. Nucleation may occur as a result of the addition of aqueous ammonia to the solution to initiate precipitation of ZnO by increasing pH. After suitable time for seed layer growth, and subsequent annealing of the seed layer, a second growth part may then be employed, such as by inserting the substrate with seed layer into an aqueous solution of zinc nitrate, sodium citrate, and aqueous ammonia, and then heating the solution, for example, from room temperature to 90° C.

Nucleation and subsequent growth of a thicker ZnO film may also be achieved in a 1-part aqueous solution process. For example, relatively high nucleation and growth rates may be achieved in a single step by using microwave heating of an aqueous growth solution, as described in Richardson, J. J. and Lange, F. F., Rapid Synthesis of Epitaxial ZnO Films from Aqueous Solution Using Microwave Heating. Journal of Materials Chemistry 2011, 21, 1859-1865. If one or more ZnO crystals are provided for ZnO to deposit on to, homoepitaxial nucleation, which typically occurs with relatively low supersaturation and may also be referred to as growth in this context, may take place with no specific aqueous solution process step or condition differentiating nucleation from growth. For example, ZnO growth may occur on one or more ZnO crystals inserted into an aqueous growth solution, wherein the one or more zinc oxide crystals may be of arbitrary form synthesized by any arbitrary method.

A rate of ZnO synthesis may potentially be affected by a variety of factors, such as solution composition, circulation rate, volume, temperature, and/or rate of temperature change, etc. As alluded to previously, if a process is formulated to at least partially affect intra-crystalline porosity, process parameters such as these may potentially be modified; however, here, these parameters are mentioned in the context of effect on rate of synthesis and potential for fabrication of crystals in a variety of forms, (e.g., epitaxial film, particle, bulk body, etc.) and, therefore, as above, are mentioned independent of considerations regarding potential affect with respect to intra-crystalline porosity.

Thus, for an embodiment, guidelines for selecting conditions for a baseline process used to fabricate different forms of ZnO may be based at least in part on the foregoing, independent of considerations related to intra-crystalline porosity. For example, if growing a bulk single crystal, a supersaturation rate may desirably be kept relatively low so as to reduce risk of a secondary nucleation and dendritic growth, which may occur at fast growth rates and may potentially lower crystal quality. Likewise, forming an epitaxial film on a substrate may imply an at least initially higher supersaturation rate to initiate nucleation, such as via a seed layer forming operation, followed by a lower supersaturation rate to facilitate more quality for single crystal film growth. Synthesis of ZnO nanowires on a substrate may involve a lower nucleation density than a film to reduce risk of growing connections between wires, but a higher supersaturation rate after nucleation to promote 1-dimensional growth. Synthesis of free nanoparticles may involve a relatively high supersaturation rate to initiate nucleation of many particles, but supersaturation may be dropped after nucleation to reduce risk of further growth.

In general, therefore, at a high level, a baseline process may comprise creating conditions to produce one of the types of nucleation, such as previously described, from a supersaturated aqueous growth solution of dissolved zinc complexes at an appropriate temperature and pH to initiate synthesis of ZnO, which may, for example, comprise epitaxial growth, precipitation of ZnO from a dissolved zinc complex in solution, etc. Thus, initially, it may be desirable to have a relatively high supersaturation rate, such as in an embodiment seeking to produce homogeneous or heterogeneous nucleation, for example. However, depending on a variety of factors, as discussed above, for example, it may also be desirable for a supersaturation rate to later be lowered for higher quality crystal growth following initial nucleation.

As previously indicated, example processes, such as those just described as a baseline, may produce an incidental amount of intra-crystalline porosity; however, porosity generated incidental to a fabrication process may not necessarily offer a set of desirable material properties, at least with respect to specific uses, particularly if desirable properties may at least partially vary relative to intended application of the material being fabricated (e.g., optoelectronic versus thermoelectric). Rather, like the intra-crystalline porosity itself, the properties that result likewise are merely incidental and, therefore, being incidental are typically viewed as not desirable. Thus, as previously indicated, porosity, such as intra-crystalline porosity, to the extent incidental intra-crystalline porosity is recognized as being present, for example, has typically been viewed as something to be reduced in fabrication of zinc oxide, since it has a risk of reducing material quality for a particular use for which the material may be being fabricated. In contrast, however, claimed subject matter is intended to encompass intra-crystalline porosity, other than incidental intra-crystalline porosity, for synthesized ZnO crystals, so that desired or desirable properties related to intra-crystalline porosity may be sought via particular processes and/or changes in process parameters, as discussed further below. That is, intra-crystalline porosity in these situations is not incidental but results from a specifically formulated process and/or approach to zinc oxide crystal growth/synthesis and/or post-synthesis treatment.

For example, a porous ZnO crystalline structure may be created in one or more embodiments, in which conditions used for ZnO crystal synthesis, along with conditions used in subsequent treatment of one or more ZnO crystals (e.g., post-synthesis), may be used to at least partially affect pore size, pore density, and/or pore shape within one or more resulting ZnO crystals. For example, by varying conditions for growth solution preparation, ZnO crystal synthesis, and/or subsequent (e.g., post-synthesis) crystal treatment, as described with more detailed illustrative examples below, it may be possible to beneficially affect resulting intra-crystalline porosity characteristics and/or associated material properties. As has been indicated previously, claimed subject matter relates to one or more zinc oxide crystals possessing internal (e.g., intra-crystalline) porosity, techniques to prepare one or more zinc oxide crystals with internal porosity, including appropriate post-synthesis treatment, and use of one or more zinc oxide crystals with internal porosity in a variety of applications which utilize properties and/or characteristics provided by having an at least approximately formulated amount of internal porosity.

As was mentioned, applications that typically use transparent conductive layers, including photovoltaic solar cells and/or LED/OLED type lighting, as non-limiting examples, may also benefit from one or more light management layers, such as one or more layers having optical properties that may include, for example, anti-reflectivity, light extraction, and/or light trapping properties. Although techniques to produce these optical properties in a separate layer are known, in general, they have a variety of disadvantages, which typically includes manufacturing complexity, cost and/or less than desirable performance.

Porous materials may be an effective alternative to existing approaches for producing one or more layers that are anti-reflective and/or may be employed to manage other optical properties, while also being transparent and conductive, in an example embodiment. Intra-crystalline porosity may, for example, provide an ability to tune a refractive index for a material, such as zinc oxide, as one example. If pore dimensions are small relative to light wavelength, light may interact with a substance as if the substance were homogeneous with a lower refractive index, where the degree of refractive index lowering may potentially be affected at least partially by a volume fraction attributable to pores, in an embodiment. This may allow tuning at least approximately to a desired “apparent refractive index.” Likewise, it may also be possible via varying intra-crystalline porosity to grade a material (e.g., layers with appropriately tuned apparent indices of refraction) to affect total internal reflection, for example. In this context, apparent and/or similar terms, if used to refer to refractive index and/or density, is intended to mean a resulting refractive index and/or a resulting density, such as for layers having porosity, as an example. Thus, a matrix material and/or a material filling the pores may each intrinsically have a different refractive index than the apparent refractive index for a porous material that includes both substances. It is likewise noted that the terminology “refractive index” may be used in places throughout this document in which the terminology “apparent refractive index” is intended; however, to reduce cumbersome repetition, the word “apparent” may be omitted.

It is believed that employing intra-crystalline porosity in a transparent conductive ZnO film has not been previously suggested or demonstrated. Rather, intra-crystalline porosity is typically viewed as a defect to be reduced and, if possible, eliminated for various materials, including zinc oxide. A layer of zinc oxide with intra-crystalline porosity may also potentially be employed in electrically-passive applications for ZnO layers, including ultraviolet (UV) light filtering and/or low emissivity coatings, as non-limiting examples.

Anti-reflection films with internal porosity, such as Royal DSM's KhepriCoat® product, are described in Same sun, more power: KhepriCoat®—the best-performing anti-reflective coating for solar cover glass, DSM Advanced Surfaces, 2012, (a brochure); however, as mentioned, this example is not within a layer that is also a transparent conductive layer. Likewise, in Kim, J. K., S. Chhajed, M. F. Schubert, E. F. Schubert, A. J. Fischer, M. N. Crawford, J. Cho, H. Kim, and C. Sone, Light-Extraction Enhancement of GaInN Light-Emitting Diodes by Graded-Refractive-Index Indium Tin Oxide Anti-Reflection Contact. Advanced Materials, Vol. 20(4): p. 801-804. 2008, a porous ITO transparent conductive film was produced having irregular tilted ITO rod-like structures; however, porosity primarily existing between the rod structures (e.g., inter-crystalline), rather than being intra-crystalline.

It is noted that state of the art processes to manufacture zinc oxide, in general, typically comprise vapor phase processes that produce dense zinc oxide. Thus, zinc oxide crystals produced in such a manner either have no measurable intra-crystalline porosity or have no more than a negligible amount of intra-crystalline porosity, such as, as an illustration, typically less than 0.1% porosity as a volume fraction and/or typically pores having an average diameter less than 1 nanometer, for example. A relatively low temperature process (e.g., 20-100 degrees C.), for example, a baseline process, such as one of the illustrative examples described previously, may produce some amount of incidental intra-crystalline porosity, meaning that some intra-crystalline porosity may result in zinc oxide crystals produced, but that process parameters for the produced zinc oxide crystals are not specifically formulated to affect resulting intra-crystalline porosity, either in whole or in part. Thus, any resulting porosity is merely incidental to manufacturing. Whereas, in this context, in contrast, claimed subject matter is intended to encompass intra-crystalline porosity other than incidental intra-crystalline porosity, as previously indicated. With porosity being produced incidentally, associated material properties are likewise incidental, whereas porosity other than incidental porosity is intended to at least partially affect material properties of resulting crystals in specific, desirable ways, as discuss below in more detail.

Thus, in an embodiment, for example, a composition of matter may comprise one or more zinc oxide crystals in which the one or more zinc oxide crystals have intra-crystalline porosity other than incidental intra-crystalline porosity, such as previously indicated, for example. As a non-limiting illustration, one or more zinc oxide crystals having intra-crystalline porosity other than incidental intra-crystalline porosity may, for example, form single crystals, such as in at least part of at least one of the following forms: an epitaxial film; a single crystal film; a single crystal particle; a bulk single crystal, or an array or a pattern of micro- or smaller dimensioned single crystal structures. Although claimed subject matter is not limited in scope in this respect, a particle may typically be less than 100 microns, whereas a bulk crystal may typically be greater than 100 microns. Likewise, one or more zinc oxide crystals may also form a polycrystalline body, such as, part of at least one of the following forms: a polycrystalline film; a polycrystalline particle; a bulk polycrystalline body, or an array or pattern of micro- or smaller dimensioned polycrystalline structures. Of course, different processes may be employed to fabricate different physical forms and geometries. Previously, in connection with discussion of a baseline process, approaches to forming particles, epitaxial films and/or bulk body crystals, for example, were discussed.

It is well established that zinc oxide may be produced by multiple types of solution crystal growth and/or deposition techniques, such as a baseline process, including illustrations described above, for example. Likewise, relatively low temperature solution type methods for synthesizing zinc oxide in the form of nanostructures, particles and powders, polycrystalline films, epitaxial films, and/or bulk single crystals are known, such as previously illustrated. As described in more detail below, however, processes may be specifically formulated, which may include various modifications to otherwise known approaches, to synthesize zinc oxide crystals having intra-crystalline porosity other than incidental intra-crystalline porosity.

Similarly, in another illustrative example, a composition of matter may comprise one or more zinc oxide crystals in which the one or more zinc oxide crystals have intra-crystalline porosity other than incidental intra-crystalline porosity in a sufficient amount so as to at least alter optical properties of one or more zinc oxide crystals. Thus, one or more aspects of reflection, transmission and/or absorption of electromagnetic radiation, including light, such as visible light, incident to the one or more zinc oxide crystals may be affected at least partially by resulting intra-crystalline porosity. Two aspects of intra-crystalline porosity that may affect optical properties of one or more zinc oxide crystals include at least partially affecting an apparent refractive index and/or at least partially affecting optical scattering.

Optical scattering by porous materials can be described by the Mie Solution to Maxwell's Equations, also referred to as Mie scattering, or the Rayleigh Approximation, if pore size is small relative to light wavelength, also referred to as Rayleigh scattering. Optical scattering depends at least in part on pore size and light wavelength, such that, for a sufficiently small pore size relative to the light wavelength, optical scattering may be relatively low. In some situations, however, relatively high optical scattering may be desirable.

Relatively high scattering may be desirable, for example, to diffusely scatter electromagnetic radiation, such as light, including visible light. While relatively low scattering may produce transparency, relatively high diffuse scattering may produce opacity and/or translucency, for example. Likewise, scattering may be employed in some devices to improve efficiency. For example, for an optoelectronic device, such as a light emitting diode (LED) or an organic light emitting diode (OLED), relatively high scattering in one or more light extraction layers may allow more light to be emitted by scattering guided and/or trapped light out of a device.

Porosity may also affect apparent refractive index, as alluded to previously. If dimensions of pores are, again, small relative to light wavelength, a porous material may be treated and/or viewed as a single medium or substance, in terms of interaction of the material with that light wavelength. An apparent refractive index may, therefore, be estimated substantially in accordance with the Lorentz-Lorenz equation as follows:

$$\frac{{n}_{eff}^{2} - 1}{{n}_{eff}^{2} + 2} = P \frac{{n}_{p}^{2} - 1}{{n}_{p}^{2} + 2} + ( 1 - P ) \frac{{n}_{m}^{2} - 1}{{n}_{m}^{2} + 2}$$

where n_{eff} is an apparent refractive index of a porous material, nₚ is a refractive index of a secondary material, e.g., material filling the pores, nₘ is a refractive index of a first or base material, e.g., matrix material between the pores, and P is pore fraction. If pores are filled with a relatively low refractive index medium, like a gas or a vacuum, apparent refractive index typically is reduced relative to refractive index of the nonporous, matrix material, for example. Alternative so-called “effective medium approximations” other than the above Lorentz-Lorenz equation, such as, for example, the Maxwell-Garnett or Bruggeman models, as well as numerical modeling methods, may be used in a similar fashion to estimate apparent refractive index of a porous material.

A change to an apparent refractive index of a porous material may be used to change the degree of reflection and/or refraction of electromagnetic radiation that occurs at an interface (e.g., physical boundary) between a porous material and another medium or material. Employing the Fresnel Equations, a fraction of light reflected, if passing from a medium of refractive index nᵢ to a medium of refractive index nₜ, may be estimated to be substantially in accordance with the following:

$${R}_{tot} = {R}_{s} + {R}_{p} , \\ where$$

$${R}_{s} = {[ \frac{{n}_{i} cos {θ}_{i} - {n}_{t} \sqrt{1 - {( \frac{{n}_{i}}{{n}_{t}} sin {θ}_{i} )}^{2}}}{{n}_{i} cos {θ}_{i} + {n}_{t} \sqrt{1 - {( \frac{{n}_{i}}{{n}_{t}} sin {θ}_{i} )}^{2}}} ]}^{2}$$

$$and$$

$${R}_{p} = {[ \frac{{n}_{i} \sqrt{1 - {( \frac{{n}_{i 1}}{{n}_{t}} sin {θ}_{i} )}^{2}} - {n}_{t} cos {θ}_{i}}{{n}_{i} \sqrt{1 - {( \frac{{n}_{i 1}}{{n}_{t}} sin {θ}_{i} )}^{2}} + {n}_{t} cos {θ}_{i}} ]}^{2} ,$$

and where Rₛ is the reflection for s-polarized light, Rₚ is the reflection for p-polarized light, and θᵢ is angle of incidence.

Thus, it may be possible to reduce overall reflection by inserting a medium of intermediate refractive index between nᵢ and nₜ mediums, such as where an apparent refractive index of a medium is between nᵢ and nₜ mediums, for example. This may be done so that reflections from the interfaces (e.g., physical boundaries) of the additional material sum to less than reflections from the mediums without the additional material. Combined reflection is minimized at least mathematically if the inserted or additional medium has a refractive index, such as an apparent refractive index, equal to the square root of the product of the refractive indices of surrounding mediums, here two other mediums. Further reduction in overall reflection may result from additional layers. In theory, a lowest possible reflection may result from an infinite number of layers with a refractive index contrast, such as using apparent refractive index, for example, approaching zero, that is, one in which apparent refractive index is continuously varying, at least approximately.

Changes in intra-crystalline porosity characteristics may be employed so that an apparent refractive index, but still other than the refractive index of dense ZnO (e.g., negligible or no measurable intra-crystalline porosity), for a layer of ZnO may be made to be reasonably uniform and/or may be made to have a reasonably consistent variation at least approximately as a function of location within one or more layers including one or more zinc oxide crystals, in any one of three spatial dimensions, or combinations thereof. Thus, an appreciable reduction in apparent refractive index for one or more zinc oxide crystals for at least one or more frequencies of light may be possible. Typically, for example, and discussed by example later, a device, such as a semiconductor device, may be layered. In one example, a layer of ZnO may, for example, be sandwiched between two layers, one with a higher refractive index and one with a lower refractive index. Thus, a layer of ZnO with an apparent refractive index that falls between the respective indices of the respective layers may reduce reflections, for example. As discussed above, a composition of matter having a desired apparent refractive index may be fabricated by affecting internal porosity at least partially.

A reduction of apparent refractive index generated using, here, intra-crystalline porosity, may result in a change in transmission and/or reflection of at least one or more frequencies of light, for at least one or more angles of incidence, at one or more physical boundaries with an immediately adjacent layer to the one or more layers including one or more zinc oxide crystals, as explained. A reduction of apparent refractive index may result in a change in optical confinement and/or wave guide properties for one or more optical modes, in one or more layers that includes one or more zinc oxide crystals and/or one or more immediately adjacent layers, for one or more frequencies of light. Thus, absorption of light by a device, as well, may potentially be affected since light in a particular instantiation may have a longer path length due to being reflected or guided within a layer and/or within a device.

Along similar lines, an appreciable change in optical scattering properties of one or more zinc oxide crystals for at least one or more frequencies of light may also be possible. As with refractive index, such as apparent refractive index, a change in optical scattering properties may be made to be reasonably uniform and/or may be made to have a reasonably consistent variation at least approximately as a function of location within one or more layers including one or more zinc oxide crystals. Thus, a change in optical scattering properties may result in a change in transmission, reflection and/or absorption of at least one or more frequencies of light, for at least one or more angles of incidence for the one or more layers that may include one or more internally porous zinc oxide crystals. Likewise, a change in optical scattering properties may result in a change in optical confinement and/or wave guide properties for one or more optical modes, in one or more layers that includes one or more internally porous zinc oxide crystals and/or one or more immediately adjacent layers, for one or more frequencies of light.

As a result of fabrication, as suggested, intra-crystalline porosity other than incidental intra-crystalline porosity, may be made to vary in a reasonably consistent manner approximately as a function of location within one or more zinc oxide crystals, in any one of three possible spatial directions, or combinations thereof. For example, a reasonably consistent variation may comprise an approximately continuous or an approximately step-wise variation. Likewise, alternatively, intra-crystalline porosity other than incidental intra-crystalline porosity may be made to be reasonably uniform approximately as a function of location within one or more zinc oxide crystals as a result of fabrication.

For example, as discussed below in more detail, various conditions may be adjusted to at least partially affect intra-crystalline porosity for one or more zinc oxide crystals being formed (e.g., grown) in terms of nature and/or degree. Thus, material with an apparent refractive index that varies in one or more steps, or a continuous manner, in one or more of three spatial dimensions of a ZnO crystal, may potentially be fabricated, such as, for example, by varying conditions under which one or more ZnO crystals are synthesized from solution. For example, composition, rate of flow or exchange, and/or temperature of a growth solution used may be varied as one or more ZnO crystals are synthesized. These changes in conditions may affect one or more resulting ZnO crystals grown in terms of concentration of defects and/or nature thereof, in accordance with at least one theory, for example. A change in nature and/or degree of porosity may alter apparent refractive index and/or optical scattering properties, as desired. Thus, employing various approaches, such as those discussed below, it is possible to determine and generate at least approximately suitable pore characteristics for a range of desirable optical properties, including for a desired apparent refractive index and/or for desired light scattering behavior, for example.

In yet another illustrative example, a composition of matter may comprise one or more zinc oxide crystals in which the one or more zinc oxide crystals have intra-crystalline porosity other than incidental intra-crystalline porosity of a sufficient amount so as to at least alter thermal conductivity and/or electrical conductivity of the one or more zinc oxide crystals. Any relative change in respective conductivities (e.g., thermal conductivity and/or electrical conductivity) may not be commensurate, for example, at least partially due to a greater degree of phonon scattering than electron scattering by the pores. In this regard, porous semiconductors have been demonstrated as potentially high figure of merit thermoelectric materials. Intra-crystalline porosity for one or more zinc oxide crystals, for example, may produce a larger reduction in thermal conductivity than in electrical conductivity, which may consequently result in improved thermoelectric performance. PCT/US2011/025810 (WO2011106347), Francois, E. J. P., G. Guzman, and P. Marudhachalam, “A process for manufacturing a doped or non-doped zno material and said material”, published Sep. 1, 2011, addresses thermoelectric considerations for inter-crystalline porosity (not intra-crystalline porosity) for zinc oxide. Intra-crystalline porosity, however, could potentially be used to achieve even better thermoelectric performance than shown with inter-crystalline porosity for a given pore volume fraction. For example, as discussed previously, intra-crystalline porosity potentially may be employed to ‘decouple’ grain size and pore size, or may even allow for use of porous single crystals or epitaxial films with no grain boundaries in effect in an embodiment, for example.

As mentioned above, a composition of matter may comprise one or more zinc oxide crystals in particle form, again, with one or more zinc oxide crystals having intra-crystalline porosity other than incidental intra-crystalline porosity. In particle form, one or more zinc oxide crystals may, therefore, comprise a constituent of one or more mixtures in which the one or more mixtures may, for example, comprise one or more of the following products: cosmetics, ink, sunscreen, paint and/or other types of coating. These products represent a set of applications where a capability to affect an apparent refractive index of a material, such as zinc oxide, here, may be desirable, including for personal care products (e.g., cosmetics), and/or protective coatings (e.g., paint and/or coatings to block or at least filter ultraviolet light), for example.

Scattering cross-section of a material, such as of a zinc oxide particle, is related to apparent refractive index for the material, here, zinc oxide, as well as particle size and shape, with smaller physical dimensions and lower refractive indices generally leading to smaller scattering cross-sections. Thus, density, size and/or shape of intra-crystalline porosity may likewise be employed to affect scattering cross-section. This may be particularly desirable in situations in which it is desirable to reduce use of nano-sized particles, such as for reasons that may include at least one of the following: processability, health, safety, and/or a combination thereof, etc. Thus, as one example, a larger zinc oxide particle may exhibit a desired smaller scattering cross-section, such as in sunscreen applications, in which it may be desirable for a formulation to appear transparent rather than opaque if applied to human skin, for example, such as for reasons previously suggested, for example.

Another feature of intra-crystalline porosity, such as one or more zinc oxide crystals having intra-crystalline porosity other than incidental intra-crystalline porosity, may comprise an increase in effective surface area. That is, additional intra-crystalline porosity may effectively increase available surface area. In general, catalytic reactions often take place at the surface of the catalyst. Therefore, increased surface area from additional intra-crystalline porosity may affect the catalysis of a reaction in appropriate circumstances. One or more zinc oxide crystals may therefore potentially be employed as a heterogeneous catalyst and/or as a constituent of a composite heterogeneous catalyst.

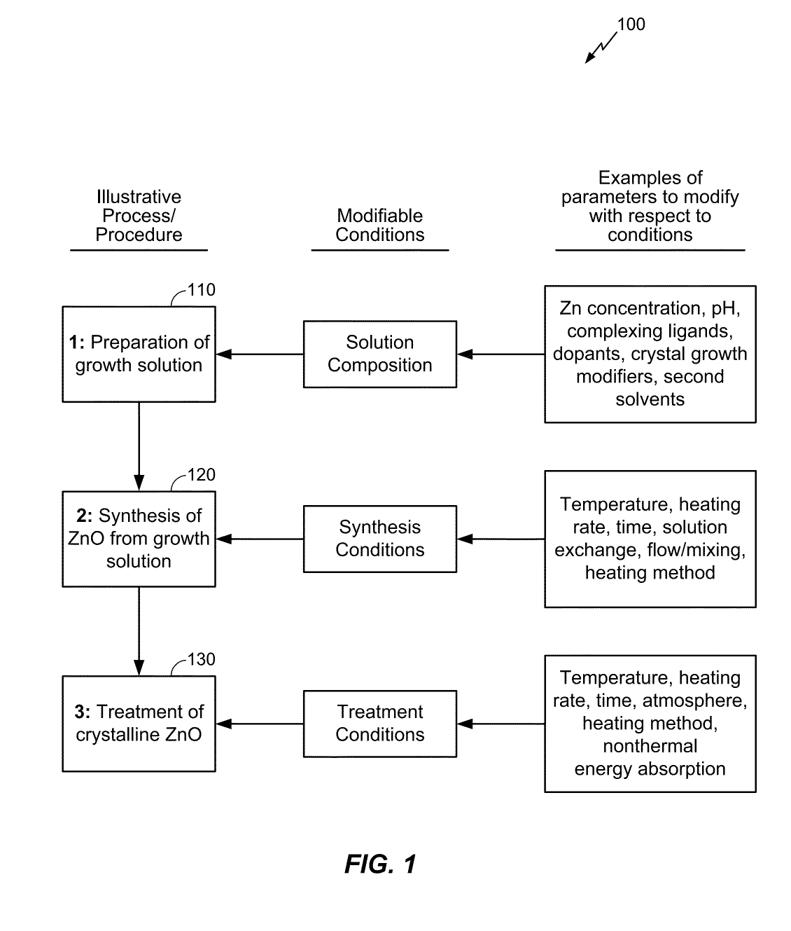

As illustrated in FIG. 1, there are three general (e.g., high-level) operations (e.g., tasks) to be performed to generate one or more zinc oxide crystals possessing internal porosity (e.g., intra-crystalline porosity) other than incidental intra-crystalline porosity. ZnO crystals may be synthesized by hydrothermal growth, chemical bath deposition, electro-deposition, electro-less deposition, successive ionic layer adsorption and reaction, spin spray deposition, and/or any related solution type method in which ZnO is crystallized in-situ, and directly from zinc ions and/or complexes dissolved in solution. For example, a suitable aqueous growth solution may be prepared from which one or more zinc oxide crystals are to be synthesized, shown by block 110. Likewise, synthesis of one or more zinc oxide crystals may take place in the aqueous growth solution, shown by block 120. Finally, after synthesis of crystals, further crystal treatment (e.g., post-synthesis) may take place, shown by block 130.

Also, as shown, specific conditions used in any of the foregoing may be potentially varied to at least partially affect intra-crystalline porosity, including affecting degree and/or nature thereof at least partially. For example, in accordance with theory at least, variations in synthesis conditions may at least partially affect a rate of incorporation of defects in one or more ZnO crystals being formed, e.g., substitutional dopants, substitutional impurities, interstitial dopants, interstitial impurities, atomic vacancies, second phases (for example, a zinc hydroxide phase which reacts to form pores during and/or subsequent to ZnO synthesis), etc. As another example, variations in synthesis conditions may at least partially affect a rate of incorporation of defects in ZnO crystals being formed, but without directly affecting defects that react to form pores, but by at least partially directly affecting catalysis or nucleation of pores and/or by at least partially altering mobility of other defects that react to form pores, so that nucleation density and/or growth rate of pores may be at least partially affected, again, at least in accordance with theory. Likewise, variations in post-synthesis treatment of ZnO crystals may at least partially affect pore formation, such as variations in an annealing temperature, duration, heating rate, cooling rate, ambient atmosphere, exposure to non-thermal energy, such as microwaves, ultraviolet light, relatively high intensity visible light (e.g., from a laser), exposure to a plasma, a liquid, and/or to a supercritical fluid treatment process, as previously discussed, for example.

In an embodiment, therefore, one or more zinc oxide crystals with internal porosity other than incidental intra-crystalline porosity may be formed by synthesizing one or more zinc oxide crystals in a manner so that pores may be formed within the matrix of a crystal as a result of exposing the one or more crystals to certain conditions. For example, if a crystal has been synthesized to possess less than full theoretical density for a zinc oxide crystal, such as resulting from a presence of defects and/or impurities, this may occur, at least in theory. In some embodiments, this may occur from synthesizing one or more zinc oxide crystals with a low temperature aqueous synthesis process. For example, one theory may be that low temperature synthesis process conditions used potentially result in one or more zinc oxide crystals with a relatively high concentration of hydrogen impurity defects and/or zinc vacancy defects incorporated in the crystal structure, which with post-synthesis treatment (which may, for example, include heating the one or more zinc oxide crystals) may react to release water vapor and form Zn and O vacancy pairs, which may in turn combine to form pores. Likewise, intra-crystalline porosity that is formed may be affected in nature and/or degree at least in part by varying conditions of synthesis and/or post-synthesis treatment, as discussed previously.

Thus, as one illustrative embodiment, a fabrication process may comprise forming one or more zinc oxide crystals at least partially in an aqueous solution, such as for a particular application of synthesized zinc oxide crystals, including applications previously described, for example. One or more zinc oxide crystals may, for example, be formed in a manner so that one or more resulting zinc oxide crystals have intra-crystalline porosity that is more effective for a particular application, at least relative to zinc oxide crystals capable of being formed by a baseline process, such as one of the sample illustrative baseline processes previously described, for example. One or more resulting zinc oxide crystals fabricated, as described below, for example, have intra-crystalline porosity that is more effective for a particular application at least in part because it is other than incidental. In particular, one or more zinc oxide crystals may be formed in a manner so as to at least partially modulate resulting intra-crystalline porosity to produce a more desirable resulting intra-crystalline porosity for a particular application of zinc oxide, for example. Thus, one or more zinc oxide crystals may be formed in a manner so as to at least partially modulate resulting intra-crystalline porosity by fabrication techniques specifically formulated to at least partially affect formation of the one or more zinc oxide crystals and resulting non-incidental intra-crystalline porosity.

As has been noted, porosity that results may be varied in a host of different of ways, such as through adjustment of process parameters. For example, at least some pores in one or more resulting zinc oxide crystals may comprise pores of substantially uniform size, shape and/or density. Likewise, at least some pores in one or more resulting zinc oxide crystals may comprise pores not of substantially uniform size, shape and/or density. An average pore diameter in one or more resulting zinc oxide crystals may approximately be in the range from approximately 1 nm to approximately 100 nm, as an illustration. Volume fraction of generated porosity may also vary, such as by approximately being between approximately 1% and approximately 25%. Also previously mentioned was a capability to form one or more crystals in a film form, a particle form and/or a bulk body form, such as, for example, an epitaxial film, a polycrystalline film, or a micro-structured or smaller structured film; a single crystal particle, a polycrystalline particle, or a micro-structured or smaller structured particle; and/or a bulk single crystal, a bulk polycrystalline body, or a micro-structured or smaller structured bulk body.

As mentioned previously, at least some pores in one or more resulting zinc oxide crystals may comprise pores having a reasonably consistent variation in size, shape and/or density at least approximately as a function of location within the one or more resulting zinc oxide crystals. As a result, an apparent density of one or more resulting zinc oxide crystals may be modified by generation of more effective (e.g., other than incidental) intra-crystalline porosity in the one or more crystals, for example.

As FIG. 1 illustrates, varying parameters of an illustrative procedure, such as 100, may at least partially affect generated intra-crystalline porosity, e.g., other than incidentally generated intra-crystalline porosity, in this context. For example, faster crystal growth rates may result in material with lower apparent crystal density than slower crystal growth rates. According to one theory, faster growth rate, for example, may produce more defects in a growing crystal since there may be less opportunity for atoms to rearrange on a surface into a lowest energy configuration before additional layers of atoms may be deposited. Likewise, for synthesis from an aqueous solution, faster growth rates may at least in theory potentially also produce higher residual hydrogen and atomic vacancies in a ZnO crystal since there may be a greater amount of incomplete conversion to crystal form from soluble Zn ions containing hydroxyl ligands.

In connection with growth rate, again, referring to FIG. 1, it may, therefore, be beneficial to alter chemical composition of an aqueous solution from which one or more ZnO crystals may be synthesized. For example, under certain aqueous solution conditions, such as those described previously, synthesis of one or more ZnO crystals may result from a decrease in equilibrium solubility of ZnO from heating. Changes to chemical composition, such as those at least partially affecting pH, concentration and/or availability of zinc complexing ligands, may at least partially change a solubility differential for a given temperature change and thus, may consequently alter rate of ZnO crystal growth.

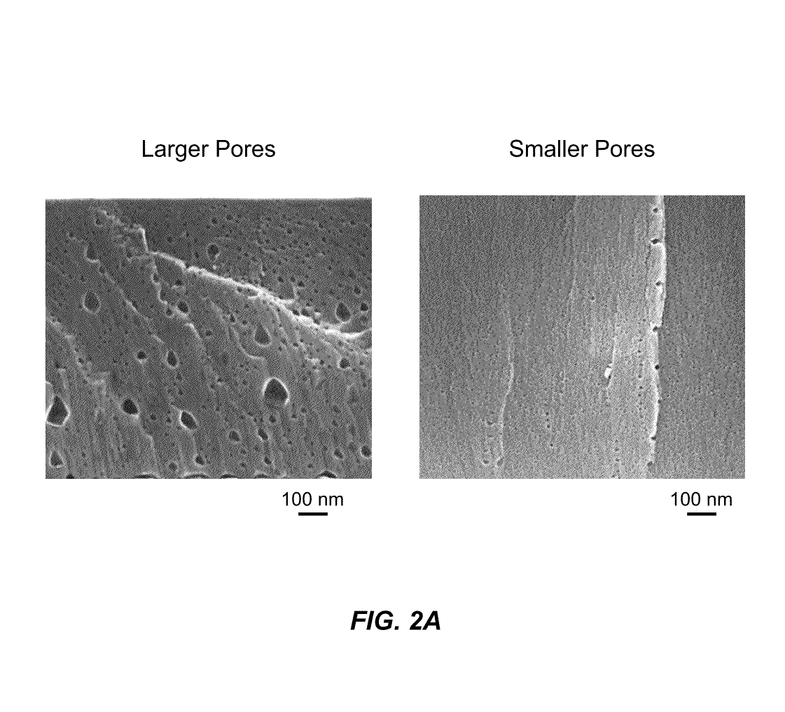

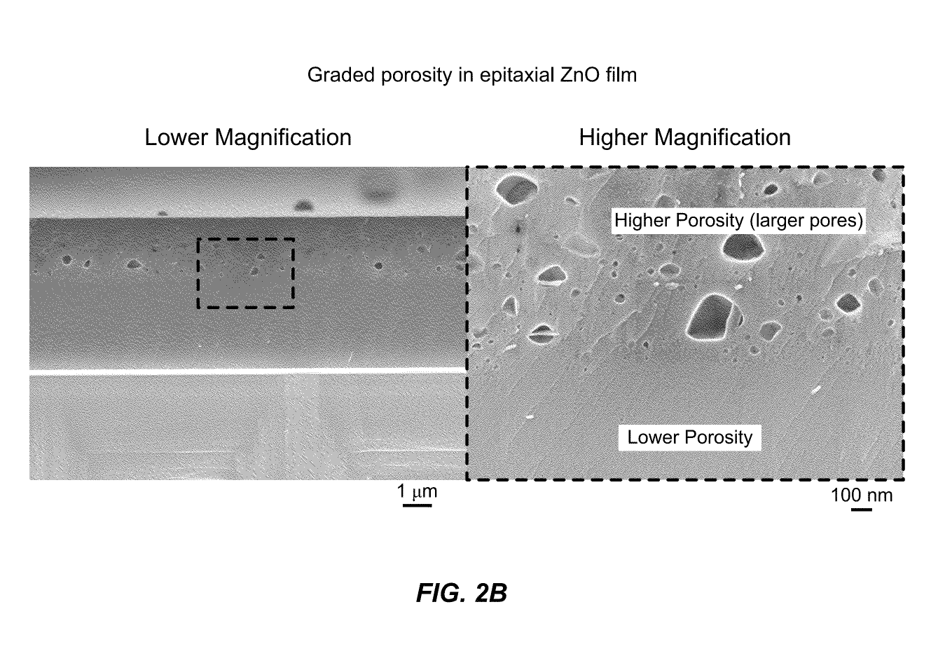

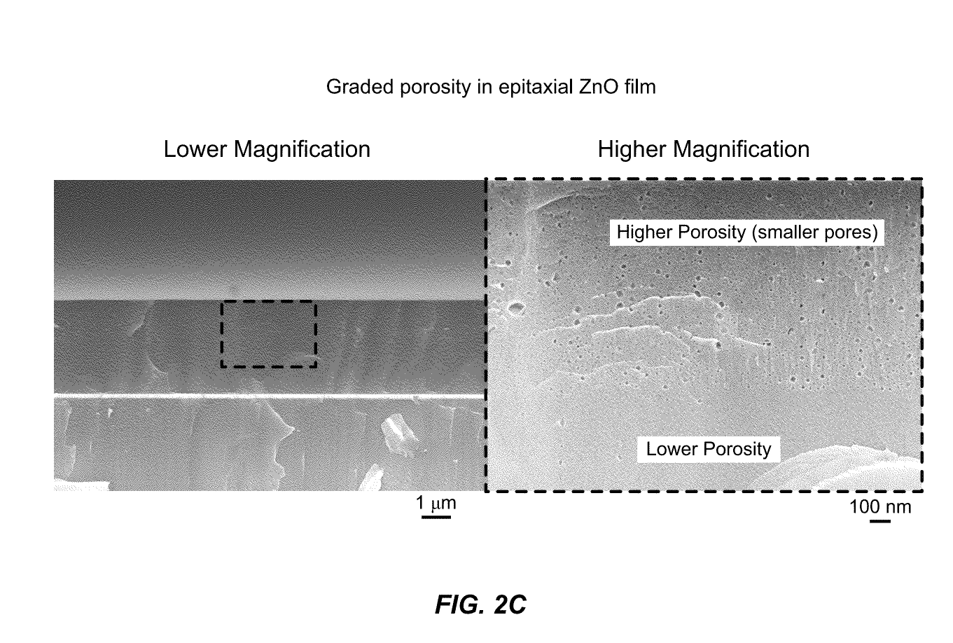

As another example, concentration of gallium ions in a growth solution used for synthesis may be altered. FIG. 2 contains images to illustrate that increasing concentration of Ga ions in an otherwise similar growth solution potentially results in a lower pore volume fraction and/or smaller pore dimensions using otherwise similar thermal annealing conditions. Thus, FIG. 2a shows two images side-by-side in which a lower Ga dopant concentration in a growth solution resulted in larger pore dimensions for ZnO grown epitaxially as a single crystal. Likewise, FIGS. 2b and c provide examples of modified Ga dopant concentration in which two layer step-graded intra-crystalline porosity was generated. Thus, Ga dopant concentration was lower for FIG. 2b than for FIG. 2c. Other ions with similar behavior, aluminum and/or indium for example, could have a similar effect if incorporated into a growth solution for zinc oxide.

In another embodiment, rate of ZnO crystal growth may be at least partially affected by supply of reactants in an aqueous growth solution from which one or more ZnO crystals are to be synthesized. For example, an aqueous growth solution from which a ZnO crystal is to be synthesized may be periodically exchanged and/or may be continuously flowing so as to provide a fresh supply of reactant species to replace those consumed by synthesis. Thus, rate of exchange and/or flow may be expected to alter rate of ZnO crystal growth.

Likewise, in still another approach, temperature of one or more ZnO crystals during synthesis and/or temperature of an aqueous solution from which one or more ZnO crystals are to be synthesized may at least partially affect rate of crystal growth. Similar to preceding approaches, higher temperatures during synthesis at least in theory allow more atoms being added to a surface of a growing crystal to find lower energy configurations. Higher temperatures provide additional energy for atomic mobility and for overcoming activation energy barriers, for example, again at least in theory. For synthesis of one or more ZnO crystals from aqueous solution, as well, theoretically lower temperatures would be expected to produce higher residual hydrogen and atomic vacancies in a ZnO crystal from increasing an amount of incomplete conversion of soluble Zn ions containing hydroxyl ligands.

Thus, as discussed, in an embodiment in which an aqueous solution comprises a crystal growth solution, the crystal growth solution may be prepared with a chemical composition specifically formulated to vary rate of zinc oxide crystal growth and thereby potentially affect internal crystal porosity at least partially. For example, a chemical composition may have a modified concentration of one or more of the following: pH; dopants and/or other impurities; one or more growth modifying agents; zinc; zinc complexing ligands; or any combination thereof. Likewise, as discussed, a crystal growth solution with a modified temperature and/or a modified pressure may be employed in an embodiment. Similarly, in an embodiment, modifying supply, flow, and/or circulation, such as of a crystal growth solution, may be employed. Likewise, any combination of the foregoing may be employed in an embodiment, of course.

As suggested previously, use of different thermal annealing conditions may also be employed in one or more embodiments, typically post-synthesis. Porosity may, for example, again, according to a theory, be a result of reactions between defects in a ZnO crystal, and therefore, rate of pore nucleation and growth may be related to diffusion of those defects and activation energies of the relevant reactions. Thus, annealing conditions, which may include changes in temperature, time, heating rate, cooling rate, etc., may affect resulting intra-crystalline porosity at least partially.

Likewise, exposing one or more ZnO crystals to energy other than thermal energy may similarly at least partially affect resulting intra-crystalline porosity. If non-thermal energy were to be absorbed by a synthesized crystal, mechanisms similar to those affecting porosity as a result of absorption of thermal energy may be at work for non-thermal energy. For example, other sources of energy that may be absorbed by one or more ZnO crystals may include visible light, ultraviolet light, microwaves, radio waves, acoustic/ultrasonic waves, direct or alternating electrical currents, etc.

Thus, in an embodiment, after synthesis, one or more formed zinc oxide crystals may be treated so that more (e.g., additional) energy is imparted to the synthesized one or more crystals during treatment (e.g., post-synthesis). As mentioned, more energy may be imparted during treatment by heating the one or more synthesized zinc oxide crystals, which may take place, for example, in a gaseous environment or a liquid environment. Likewise, more energy may be imparted during treatment by irradiating the one or more synthesized zinc oxide crystals, as was suggested, with, as examples, radio waves, microwaves, ultraviolet light or any combinations thereof.

Previously, compositions of matter with modified apparent indices of refraction and/or light scattering properties were discussed. In one or more embodiments, changing conditions under which one or more ZnO crystals are synthesized from solution, including, as examples, chemical composition, rate of flow and/or exchange, growth solution temperature, etc., may be modified in varying amounts as one or more ZnO crystals are being synthesized. As one non-limiting illustration, in a step-wise and/or continuously varying fashion, porosity may be made to differ in different regions of a synthesized ZnO crystal and in various spatial orientations, if desired. As previously discussed, changes in porosity may at least partially affect optical properties, such as an apparent refractive index and/or optical scattering.

Thus, a process may be employed to produce a reasonably consistent variation, such as a step graded variation or a continuously graded variation, to result in an apparent refractive index at least approximately as a function of location within one or more resulting zinc oxide crystals for at least one or more frequencies, again, in any of the three spatial orientations, including combinations thereof. Alternatively, a process may be employed to produce a reasonably uniform apparent refractive index at least approximately as a function of location within one or more resulting zinc oxide crystals for at least one or more frequencies, in any of the three spatial orientations, including combinations thereof.

As has been suggested, various devices, particularly but not exclusively semiconductor devices, may employ electrically conductive layers, films and/or coatings that also may have particular optical properties, including, for example, being transparent. Other examples have been anti-reflectivity, light extraction and/or capturing (e.g., trapping) light. It has been discussed, for example, that transparency and anti-reflectivity may potentially be accomplished together in one film, layer and/or coating or with one set of layers, films and/or coatings, in an embodiment. Examples of compositions of matter that may be produced in this regard have been illustrated, as well as approaches to determine at least approximately pore characteristics for such compositions of matter. Likewise, below, we provide, as non-limiting illustrations, devices that may be fabricated in accordance with various approaches, including those previously discussed.

Thus, for example, in an embodiment, a device, such as a semiconductor device, may be fabricated to include one or more zinc oxide crystals to form at least part of a layer, film and/or coating. For example, a device may comprise at least one of an optical, optoelectronic, and/or electrical device. As an example, a variety of optoelectronic devices may benefit from one or more layers comprising a composition of matter as previously described, including at least one of the following: an LED; a laser diode; an OLED; a photovoltaic cell; a liquid crystal display; a touch sensor display; a suspended particle device, an electrochromic device, or combinations thereof. For example, one or more films, layers and/or coatings of a device may comprise a transparent electrode, as discussed.

One example embodiment comprises a light emitting diode (LED) device, such as an III-Nitride type LED device. LEDs, such as III-Nitride type LEDs, are well-known. For example, GaN comprises an example of a material that may be doped appropriately by N-type and/or P-type dopants to form layers for an LED structure, for example. Fabrication of GaN layers of an LED structure, therefore, need not be discussed further. Nonetheless, an example structure is shown, for example, in Reading, A. H., J. J. Richardson, C.-C. Pan, S. Nakamura, and S. P. DenBaars, High efficiency white LEDs with single-crystal ZnO current spreading layers deposited by aqueous solution epitaxy, Opt. Express, Vol. 20(S1): p. A13-A19. 2012, as FIG. 1. For example, an LED active layer may be sandwiched between an N-type GaN layer and a P-type GaN layer. Likewise, a sapphire substrate may be employed in a typical embodiment.

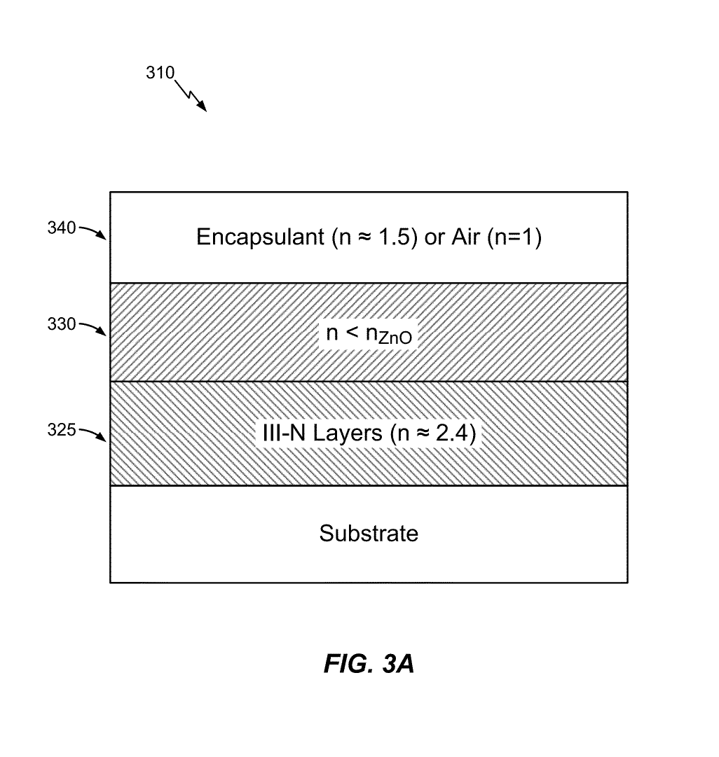

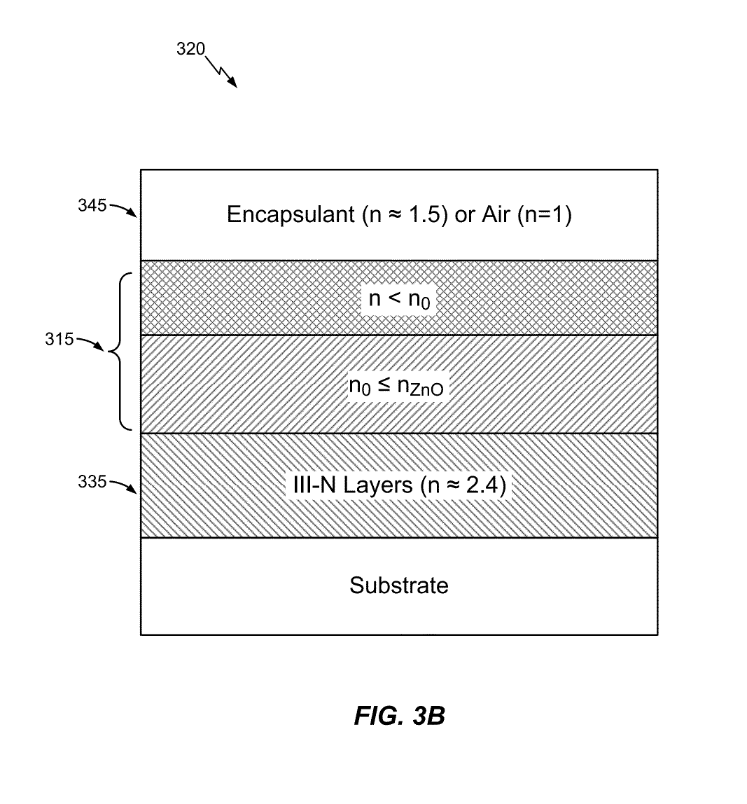

An III-Nitride type LED, such as described above, is depicted in FIG. 3a, as an LED embodiment 310. Of course, this figure is simplified for purposes of illustration and/or convenience. However, as shown, in FIG. 3a, a top LED layer 325 may comprise P-type GaN, as was described above. Likewise, embodiment 310, as shown, further comprises a porous transparent conductive ZnO layer 330 situated between P-type GaN layer 325, just mentioned, and a lower refractive index medium 340, such as a polymeric LED encapsulant or air, as shown in FIG. 3a. Porosity characteristics of ZnO in this example may be such that an apparent refractive index of porous ZnO may be reduced relative to dense ZnO at a wavelength to be emitted. For example, porosity may be of a reasonably uniform density such that a ZnO layer, such as 330 in this example, possesses a reasonably uniform apparent index that is less than that of a fully dense (e.g., negligible intra-crystalline porosity) ZnO layer, e.g., n≈2.1 for 450 nm light.

As previously explained, a layer with an apparent refractive index between the indices of the discussed III-Nitride layer, e.g., n≈2.5 for blue light, and the low index surrounding material, e.g. an encapsulant layer or air, respectively n≈1.5 or 1, may be employed. This additional layer, such as 330, in embodiment 310, for example, may produce a reduction in total reflected light, e.g., the combination of light reflected from crossing two physical boundaries corresponding to an added ZnO layer, such as 330 (with a lower apparent refractive index than fully dense ZnO) relative to light reflected from crossing a physical boundary between an III-Nitride layer, such as 325, and a low index surrounding material, such as 340, but without a ZnO layer. A reduction in total reflection may nonetheless potentially be improved even further for a ZnO layer, such as by having a layer with an apparent refractive index substantially equal to the square root of the product of respective reflective indices for the III-Nitride layer and the surrounding material.

Porosity characteristics may also be such that a resulting ZnO layer may have a non-uniform apparent refractive index, again, previously described. For example, in a non-limiting embodiment, such as 320 in FIG. 3b, for example, by varying an apparent refractive index of a ZnO layer, such as 315 shown between 345 and 335, from a higher apparent refractive index value (e.g., by having a relatively lower, zero, or nearly zero, pore fractional volume) immediately adjacent to III-Nitride layer 335 to a lower apparent refractive index value for the ZnO layer (e.g., by having a relatively higher pore fractional volume) immediately adjacent to relatively lower index surrounding material 345, it is possible to further reduce reflection compared to a reasonably uniform apparent refractive index layer. A variation in apparent refractive index using ZnO layers may, for example, be implemented in a substantially stepwise (e.g., graded, as illustrated by 320) manner, e.g., by using two or more ZnO layers with different apparent refractive indices, by a continuous variation of refractive index, or by a combination of these approaches, as discussed earlier. In theory at least, a continuously varying apparent refractive index may provide least reflection.

ZnO layers may, for example, be fabricated via an aqueous solution approach as described in aforementioned Reading, A. H., J. J. Richardson, C.-C. Pan, S. Nakamura, and S. P. DenBaars, High efficiency white LEDs with single-crystal ZnO current spreading layers deposited by aqueous solution epitaxy, Opt. Express, Vol. 20(S1): p. A13-A19. 2012, which is also consistent with one of the illustrative examples of a baseline process approach; however, as previously described, for an embodiment of claimed subject matter, aqueous growth solution conditions, crystal synthesis conditions and/or post-synthesis treatment conditions are suitably modified to at least partially affect intra-crystalline porosity.

Furthermore, a ZnO coating, film and/or layer, in this example, may also possess sufficient electrical conductivity to serve as a transparent current spreading layer in an LED device. A current spreading layer is typically used to provide higher lateral electrical conductance on the “P-type side” (here, referring to P-type GaN, for example; called “P-side,” hereinafter) of an active LED layer so that more uniform current injection may occur with less light being potentially blocked, or at least partially absorbed, by a metal contact. More specifically, P-type doped III-Nitride materials, such as GaN, for example, typically have lower electrical conductivity than an N-type doped counterpart. Thus, a metal contact placed directly on or over a P-type doped III-Nitride layer may result in highly localized injection of current into active, light generating, layers of an LED structure, potentially lowering device efficiency. With injection of current directly under the P-side metal contact, a portion of light may be generated within the device under the contact. The light may therefore be “shadowed” by the metal contact and may be less likely to escape. Furthermore, with localized current injection, less of the active region may be used to generate light with the area that is producing most of the light doing so under higher current density conditions. This may consequently also reduce internal quantum efficiency of the device due to the phenomenon commonly referred to as “droop”. Thus, as discussed, employing a transparent conductive electrode layer may result in more uniform current injection with less light being filtered or blocked, as is desired.

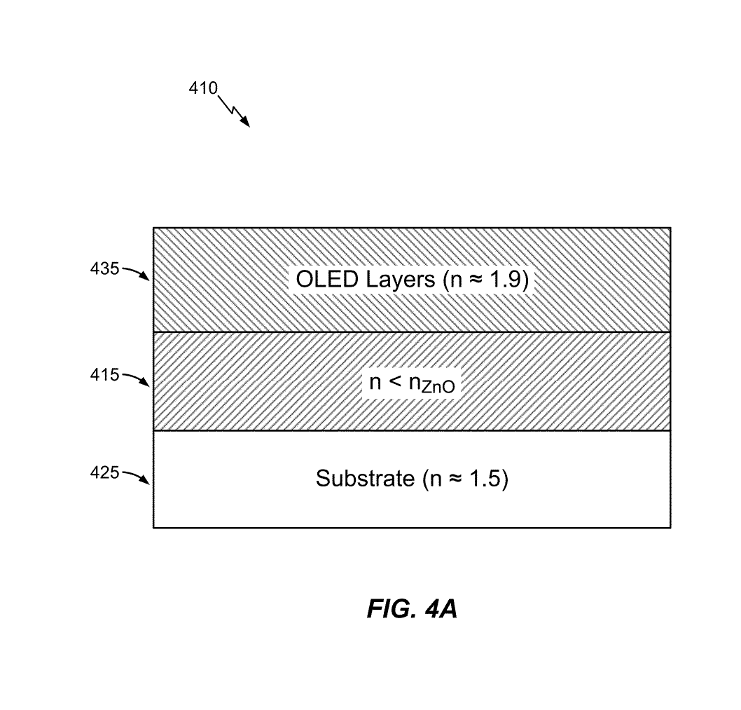

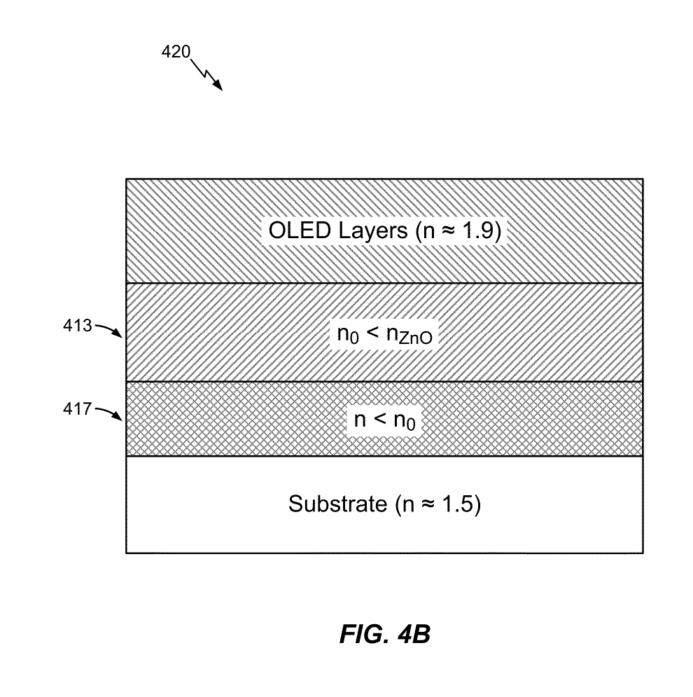

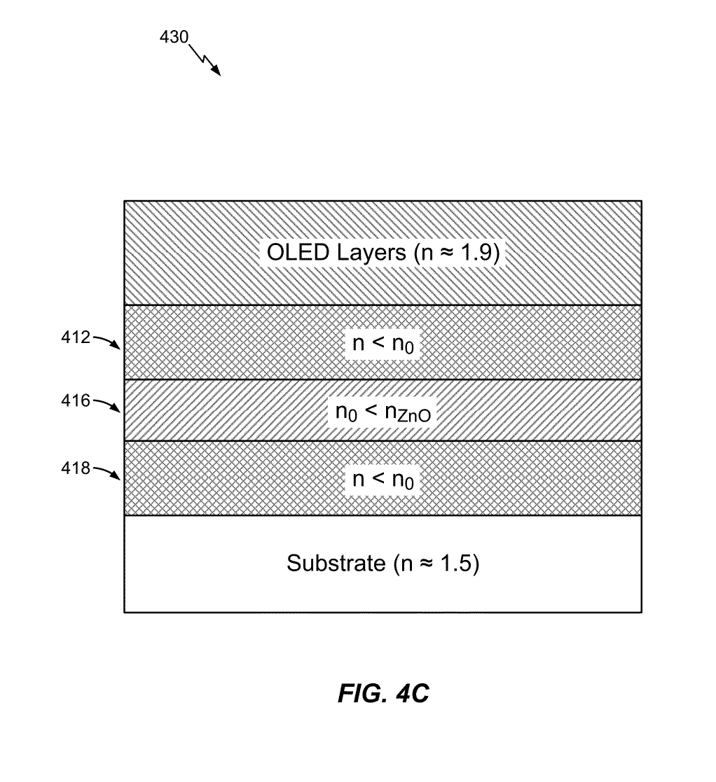

As another non-limiting example, an organic light emitting diode (OLED) device of similar structure to FIG. 3, embodiment 410 shown in FIG. 4a, may similarly comprise a porous transparent conductive ZnO layer 415 situated between a lower index substrate, like glass or a plastic polymer sheet 425, and a Hole Transport Layer (HTL) 435 of an OLED (e.g., a conducting polymer layer, such as PANI:PSS or PDOT:PSS). Substrate 425 and HTL 425 typically have refractive indexes lower than fully dense ZnO (e.g., negligible or no measurable intra-crystalline porosity). For reflections at respective physical boundaries with these materials to be reduced, a lowering of an apparent refractive index of an immediately adjacent ZnO layer may be employed. However, while both substrate 425 and HTL 435 may typically have lower refractive indices than fully dense ZnO, the refractive index of HTL 435 may still be higher than that of substrate 425. For example, glass may typically have a refractive index of approximately 1.5 and HTL may have a refractive index of approximately 1.9. Thus, reflections at physical boundaries, such as with these materials, may be further reduced by grading a ZnO layer, as shown in FIG. 4b by embodiment 420, so that an apparent refractive index of ZnO immediately adjacent to substrate 425, for example, depicted by layer 417, is lower than an apparent refractive index of ZnO immediately adjacent to HTL 435, depicted by 413 in this illustration. Lower reflections at these physical boundaries may allow more light to escape and, thus, may improve brightness and/or efficiency. However, while a relatively higher volume fraction of pores may reduce an apparent refractive index, it also may reduce layer electrical conductivity, which may be less desirable. To reduce reflection, but also reduce resistance, for a given thickness of a ZnO layer, ZnO intra-crystalline porosity may be graded so as to have lower porosity in the center of the ZnO layer with grading from the center outward to a higher porosity near substrate 425 and HTL 435, shown in FIG. 4c by embodiment 430, which includes ZnO layers 412, 416, and 418 of modulated internal porosity.

As also suggested, various devices, particularly but not exclusively semiconductor devices, may employ electrically conductive layers, films and/or coatings that also may have desired thermal properties. It has been discussed, for example, that thermal conductivity may potentially be reduced more than electrical conductivity, which may be beneficial for a thermoelectric device. Examples of compositions of matter that may be produced in this regard have been discussed.

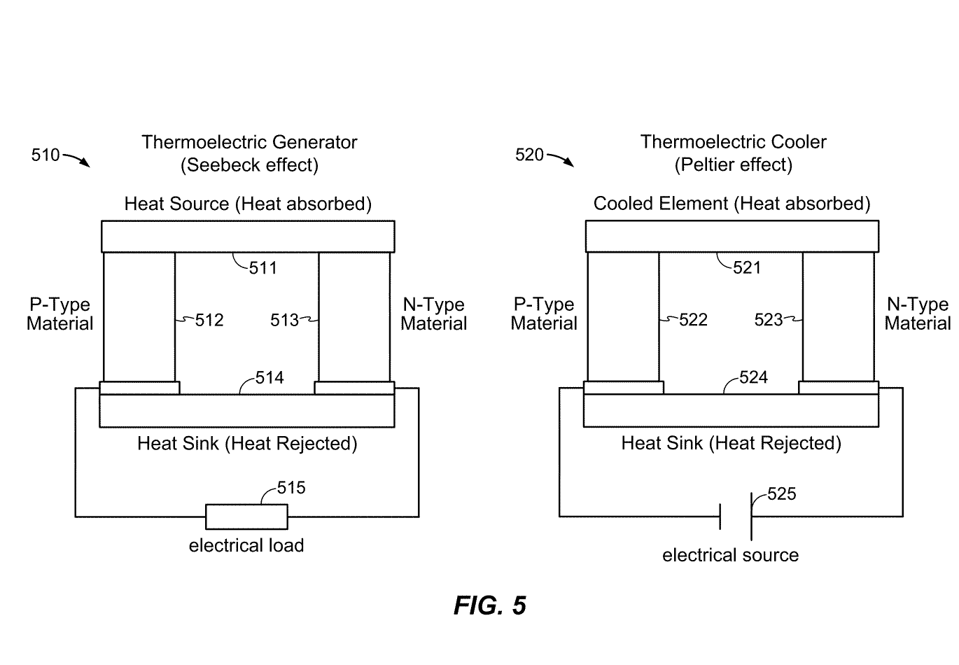

FIG. 5, therefore, is a schematic diagram showing an embodiment 510 of a thermoelectric generator device with N-type and P-type semiconductor components 513 and 512, respectively, connected electrically in series and thermally in parallel. In a thermoelectric generator device that employs the Seebeck effect at least in part, presence of a temperature gradient across a P-type component, such as 512, and an N-Type component, such as 513, maintained between a heat source 511 and a heat sink 514 supports flow of electrical current in a circuit that includes these components. A schematic diagram also shows an embodiment 520 of a thermoelectric cooling device employing the Peltier effect at least in part. In this illustration, a voltage provided for a circuit containing semiconductor components may result in flow of heat across a P-type component, such as 522, and an N-Type component, such as 523, from a heat absorber 521 to a heat sink 524. In both embodiments, e.g., thermoelectric generator and cooling devices, low thermal conductivity for a semiconductor component may be beneficial for maintaining a thermal gradient and thus, may be desirable for potentially improved device function and/or efficiency. For the embodiments shown in FIG. 5, N-Type semiconductor components, depicted as 513 and 523, may, for example, comprise ZnO having internal porosity so that lower thermal conductivity potentially may be achieved without a commensurate reduction in electrical conductivity, for example, as is desirable. An approach to fabricating an embodiment of a composition of matter having these properties was previously discussed. Thus, N-Type semiconductor components, such as 513 and/or 523, for example, may comprise one or more N-type ZnO crystals processing more than incidental intracrystalline porosity, for example. Similarly, of course, P-type components, such as 512 and/or 522, may also comprise ZnO crystals processing more than incidental intracrystalline porosity in an embodiment.

As still yet another example, a sensor may comprise one or more layers including one or more zinc oxide crystals having intra-crystalline porosity other than incidental intra-crystalline porosity. Additional intra-crystalline porosity may effectively increase available surface area, as was discussed. In general, reactions often take place at the surface of substances. A sensor device may, for example, comprise at least one of the following: a gas sensor, a chemical sensor, a biosensor, an optical sensor, a piezoelectric sensor, and/or an acousto-optic sensor. As a general principle, a particular physical phenomenon may be sensed by altering electrical properties, such as conductivity, for example. For a gas sensor, a chemical sensor and/or a biosensor, for example, a substance to be detected may interact with the pore surface, and alter measurable electrical properties of a ZnO layer, for example. Thus, a device may be fabricated so that a detected change in electrical properties signals presence of a particular substance, such as a gas. Likewise, in an alternate embodiment, perhaps a substance to be detected may interact with pore surfaces and alter measurable optical properties of a ZnO layer so as to, instead or even in addition, produce a detectable change in optical properties and thereby signal presence of a particular substance.

In the preceding description, various aspects of claimed subject matter have been described. For purposes of explanation, specifics, such as amounts, systems and/or configurations, as examples, were set forth. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be understood that the appended claims are intended to cover all modifications and/or changes as fall within claimed subject matter.

1. A composition of matter comprising: one or more zinc oxide crystals, wherein the one or more zinc oxide crystals have intra-crystalline porosity other than incidental intra-crystalline porosity.

2. The composition of matter of claim 1, wherein the one or more zinc oxide crystals form at least part of at least one of the following: an epitaxial film; a single crystal film; a single crystal particle; a bulk single crystal, or an array or a pattern of micro- or smaller dimensioned single crystal structures.

3. The composition of matter of claim 1, wherein the one or more zinc oxide crystals form at least part of least one of the following: a polycrystalline film; a polycrystalline particle; a bulk polycrystalline body, or an array or pattern of micro- or smaller dimensioned polycrystalline structures.

4. The composition of matter of claim 1, wherein the intra-crystalline porosity other than incidental intra-crystalline porosity comprises a sufficient amount so as to at least alter one or more aspects of reflection, transmission and/or absorption of light incident to the one or more zinc oxide crystals.

5. The composition of matter of claim 1, wherein the intra-crystalline porosity other than incidental intra-crystalline porosity comprises a sufficient amount of intra-crystalline porosity so as to at least alter thermal conductivity and/or electrical conductivity of the one or more zinc oxide crystals, wherein any relative change in respective conductivities is not commensurate.

6. The composition of matter of claim 1, wherein the intra-crystalline porosity other than incidental intra-crystalline porosity comprises a sufficient amount of intra-crystalline porosity so as to at least alter the optical properties of the one or more zinc oxide crystals.

7. The composition of matter of claim 6, wherein the intra-crystalline porosity other than incidental intra-crystalline porosity comprises a sufficient amount of intra-crystalline porosity so as to at least alter the apparent refractive index for the one or more zinc oxide crystals for at least one or more particular frequencies of light.

8. The composition of matter of claim 6, wherein the intra-crystalline porosity other than incidental intra-crystalline porosity comprises a sufficient amount of intra-crystalline porosity so as to at least alter one or more aspects of optical scattering by one or more zinc oxide crystals for at least one or more frequencies of light.

9. The composition of matter of claim 1, wherein the intra-crystalline porosity other than incidental intra-crystalline porosity comprises a sufficient amount of intra-crystalline porosity so as to at least alter the effective surface area of the one or more zinc oxide crystals.

10. The composition of matter of claim 1, wherein the intra-crystalline porosity other than incidental intra-crystalline porosity is reasonably uniform approximately as a function of location within the one or more zinc oxide crystals.

11. The composition of matter of claim 1, wherein the intra-crystalline porosity other than incidental intra-crystalline porosity varies in a reasonably consistent manner approximately as a function of location within the one or more zinc oxide crystals.

12. The composition of matter of claim 11, wherein the reasonably consistent variation comprises an approximately continuous or an approximately step-wise variation.

13. The composition of matter of claim 6, wherein the one or more zinc oxide crystals form at least part of a layer of an optoelectronic device, wherein the optoelectronic device comprises at least one of the following: an LED; a laser diode; an OLED; a photovoltaic cell; a liquid crystal display; a touch sensor display; a suspended particle device and/or an electrochromic device.

14. The composition of matter of claim 1, wherein the one or more zinc oxide crystals are in particle form.

15. The composition of matter of claim 14, wherein the zinc oxide of the one or more zinc oxide crystals comprise a constituent of one or more mixtures.

16. The composition of matter wherein 15, the one or more mixtures comprise a constituent of one or more of the following products: ink, sunscreen, paint and/or other types of coating, and/or cosmetics.

17. The composition of matter of claim 1, wherein the one or more zinc oxide crystals comprise a heterogeneous catalyst and/or comprise a constituent of a composite heterogeneous catalyst.

18. An apparatus comprising: an optoelectronic device; wherein the optoelectronic device includes one or more layers including one or more zinc oxide crystals having intra-crystalline porosity other than incidental intra-crystalline porosity.

19. The apparatus of claim 18, wherein the optoelectronic device comprises at least one of the following: a light emitting diode (LED); a laser diode, an organic light emitting diode (OLED); a photovoltaic cell; a liquid crystal display; a touch sensor; a suspended particle device and/or an electrochromic device.

20. A method comprising: forming one or more zinc oxide crystals at least partially in an aqueous solution for a particular application of synthesized zinc oxide crystals, the one or more zinc oxide crystals being formed in a manner so that resulting one or more zinc oxide crystals have more effective intra-crystalline porosity at least relative to zinc oxide crystals capable of being formed by a baseline process.
